(19) United States
(12) Patent Application Publication
(10) Pub. No.: US 2002/0123187 A1
(43) Pub. Date: Sep. 5, 2002

(54) Polygon-type semiconductor detector for use in high-speed X-ray CT, and manufacturing method therefor

(75) Inventor: Masaki Misawa, Ibaraki (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: National Inst. of Advanced Ind, Science and Tech., Tokyo (JP)

(21) Appl. No.: 10/058,416

(22) Filed: Jan. 30, 2002

(30) Foreign Application Priority Data
Jan. 31, 2001 (JP) 2001-23141

(51) Int. Cl. H01L 21/8238

(52) U.S. Cl. 438/200

(57) ABSTRACT

The polygon-type semiconductor detector for use in a high-speed X-ray CT according to the present invention enables a high resolution, and allows the time and cost for manufacturing to be significantly reduced, by virtue of the detection pixel group thereof having mutually homogeneous characteristics. First, X-ray modules are each constructed by arranging a plurality of X-ray detection pixels (4) formed by means of photolithography in a line on a single planar semiconductor substrate constituted of CdTe. Then, by polygonally arranging a plurality of these X-ray modules on the circumference of a measuring section around a measuring area, this polygon-type semiconductor detector is formed. Thereby, when a multiphase fluid having mutually different densities flows in the measuring area (10), this polygon-type semiconductor detector can acquire the projection data of internal density distributions at a high speed.

### TECHNICAL FIELD OF THE INVENTION

The present invention relates to a high-speed X-ray semiconductor detector used, e.g., when performing an industrial non-destructive inspection through the use of X-rays. In particular, the present invention relates to a polygon-type semiconductor detector for use in a high-speed X-ray CT, capable of being effectively utilized for visualizing the distribution of the solids and gases in an opaque fluid which is difficult to be observed by visible rays, the phase distributions in the cross section of the flow path of a multiphase flow wherein gases and liquids flow as a mixture, or the distributions in the cross section of the flow path of a powder transport pipe line. The present invention further relates to a manufacturing method for this detector.

### DESCRIPTION OF THE RELATED ART

Conventional detectors for use in X-ray CT has a structure such that scintillator-type or semiconductor-type discrete detection pixels are arranged along the circumference surrounding an object to be detected, as disclosed in e.g., Japanese Unexamined Patent Application Publication No. 10-295682. In this case, since many detection pixels cannot be processed at one time when detection pixels are arranged along such a circumference, discrete detection pixels are arranged one by one along the circumference.

Also, there is another type of X-ray CT wherein a single one-dimensional linear sensor or a single two-dimensional planar sensor is opposed to an X-ray source with an object to be detected interposed therebetween, and wherein such a sensor is mechanically rotated about the object to be detected.

In the X-ray CT according to the related art as described above, wherein discrete detection pixels are arranged one by one along the circumference surrounding an object to be detected, more detection pixels are required when attempting to enhance the resolution thereof. However, the more the number of detection pixels, the more becomes the time and cost for manufacturing, and also the higher becomes the probability of occurrence of failures. In addition, significant variations in the detection characteristic occur among detection pixels. Furthermore, in the manufacturing method wherein detection pixels are discretely arranged in such a manner, the size of a pixel has a relationship with the resolution, so that there occurs a problem that a practicable space resolution suffers a limitation.

Moreover, in the X-ray CT according to the above-described related art, wherein a linear sensor or a planar sensor is rotated, the object often moves during measurement, which causes motion artifact in the image. This raises problems in that measurement of moving objects cannot be achieved, and that a complicated driving mechanism is required for fast scanning, resulting in an increased size.

In this manner, in the conventional semiconductor detector for use in X-ray CT which detects X-rays by semiconductors, since discrete semiconductor pixels are arranged one by one around an object to be detected, much time and effort has been needed, and in addition, the accuracy thereof has been insufficient.

### SUMMARY OF THE INVENTION

Accordingly, it is an object of the present invention to provide a compact and simple-structured polygon-type semiconductor detector for use in a high-speed X-ray CT, which eliminates the need to discretely arrange detection pixels, thereby allowing this semiconductor detector for use in a high-speed X-ray CT to be manufactured inexpensively and in a shorter time than the conventional ones, which has a high endurance and a high space resolution, and which can acquire the projection data of the section of an object to be detected at a high speed. It is another object to provide a manufacturing method for the above-described detector.

In order to achieve the above-described objects, the polygon-type semiconductor detector for use in a high-speed X-ray CT according to the present invention is characterized in that a detector module is formed by unidirectionally arranging a plurality of X-ray detection pixels on a single planar semiconductor substrate, and that the X-ray semiconductor detector is formed by polygonally arranging a plurality of the detector modules around a measuring area.

As the above-described semiconductor substrate, it is effective to use CdTe semiconductor. The single semiconductor substrate is provided on a printed circuit board, and the plurality of X-ray detection pixels formed on the semiconductor substrate is arranged along the longitudinal direction of the semiconductor substrate. Preferably, the plurality of detection pixels on the single semiconductor substrate is arranged in a line. In particular, it is effective to use the X-ray detection pixels whose electrodes are made by photolithography.

The method for manufacturing a polygon-type semiconductor detector for use in a high-speed X-ray CT according to the present invention is characterized in that a plurality of detector modules consists of a plurality of X-ray detection pixels on a single planar semiconductor substrate of each of the detector modules by photolithography, and that the X-ray semiconductor detector is formed by polygonally arranging the plurality of detector modules around the measuring area.

According to the above-described polygon-type semiconductor detector for use in a high-speed X-ray CT and a manufacturing method therefor according to the present invention, it is unnecessary to discretely arrange detection pixels, and thereby the above-described semiconductor detector can be manufactured inexpensively and in a shorter time than the conventional ones. Also, according to the present invention, since detection pixels having homogeneous characteristics can be produced for each detector module, the time and cost for manufacturing can significantly been reduced, thereby allowing a high-speed, high-performance X-ray detector to be easily manufactured.

In addition, since the above-described semiconductor detector has no driving portion, the semiconductor detector has a high durability and a high space resolution, and can acquire the projection data of the sections of the object to be detected at a high speed.

Also, when the CdTe semiconductor is used as the above-described semiconductor substrate, no cooling system is needed, thereby enabling the detector to be more simple-structured and more compact.

Moreover, e.g., when performing an industrial non-destructive inspection, by arranging in a line the plurality of X-ray detection pixels formed on a single semiconductor substrate, the section of an object to be detected can be detected at one time in a planar form using a simple and inexpensive semiconductor detector. For example, even in the case of an object to be detected such as a fluid flowing in a tube, the state of the flow therein can be easily detected.

### BRIEF DESCRIPTION OF THE DRAWINGS

FIG. 1 is an enlarged plan view showing a detector module in an embodiment of a polygon-type semiconductor detector for use in a high-speed X-ray CT according to the present invention.

FIG. 2 is a sectional view showing the detector according to the embodiment of the present invention, wherein the above-described detector modules are annularly arranged along the circumference around a measured section.

### DESCRIPTION OF THE EMBODIMENTS

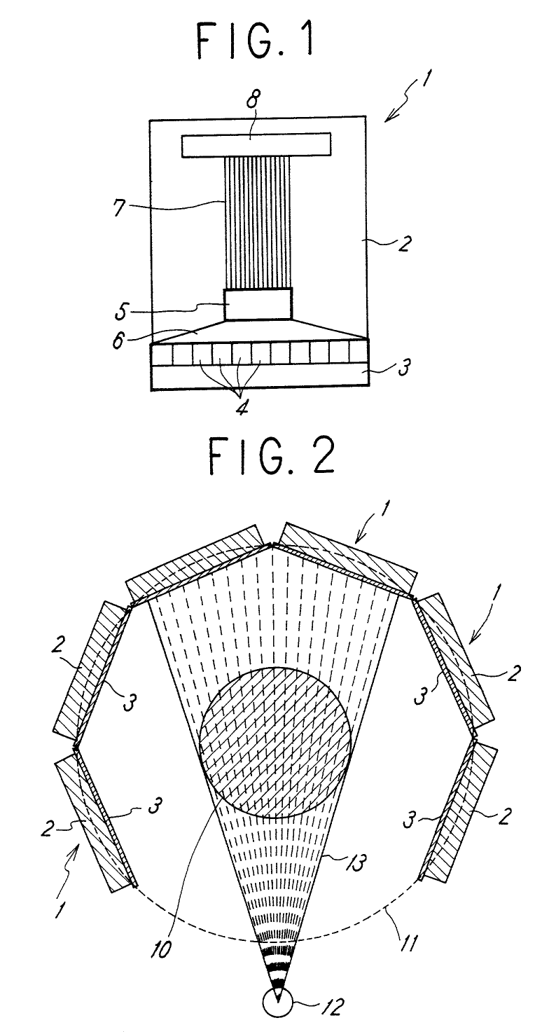

The detector module 1 in FIG. 1, used in the polygon-type semiconductor detector for use in a high-speed X-ray CT according to the present invention, has a single planar semiconductor substrate 3 provided at one end portion of a printed circuit board 2. On the semiconductor substrate 3, a plurality of X-ray detection pixels 4 are formed directly by photolithography. Also, a signal processing IC 5 is mounted on the printed circuit board 2, and the channel thereof is connected to each of the detection pixels 4 by wiring 6. The above-mentioned signal processing IC 5 and an external measurement control unit are connected through wiring 7 and a connector 8 formed on the printed circuit board 2.

As the above-described semiconductor substrate 3, it is desirable to use the CdTe semiconductor. In this detector module 1, when using the CdTe semiconductor, which is usable at room temperatures, it is unnecessary for the single semiconductor substrate 3 to have means for temperature control. In addition, since the CdTe semiconductor has an X-ray detection efficiency much higher than the X-ray detection effects of conventional semiconductor detectors such as silicon, the size-reduction of the detector module and the increasing of resolution can be achieved.

As in the illustrated embodiment, the plurality of X-ray detection pixels 4 are unidirectionally arranged on the single narrow planar semiconductor substrate 3 mounted at one end portion on the printed circuit board 2. More specifically, these detection pixels 4 are arranged along the longitudinal direction of the printed circuit board 3, and the detection pixel 4 group is formed by arranging X-ray detection pixels which are mutually homogeneous and of identical size in a line at a constant pitch. As shown in the figure, as the plurality of X-ray detection pixels 4, ones which are arranged in a single line at a minute pitch, may be used. Alternatively, however, X-ray detection pixels which are arranged in a plurality of lines may also be employed.

FIG. 2 shows the embodiment of the polygon-type semiconductor detector for use in a high-speed X-ray CT comprising the above-described detector modules 1.

When using the above-described detector modules 1 as the polygon-type semiconductor detector for use in a high-speed X-ray CT, a plurality of the detector modules 1 is polygonally arranged along the circumference 11 around the measured section at the measuring area 10, and one of X-ray sources 12 which radiates X-ray beams 13 to the measuring area 10 is placed slightly below the detector plane. This allows detection pixels 4 having mutually homogeneous characteristics to be arranged around the measuring area 10 at a minute pitch.

In using the above-described polygon-type semiconductor detector, when the X-ray beams 13 are radiated from the X-ray source 12 to the measuring area 10, all detection pixels 4 are simultaneously triggered by the external measurement control unit to have the signals thereof captured by the signal processing IC 5 after a predetermined data acquisition time.

Thereby, e.g., when a multiphase fluid having mutually different densities flows in the measuring area 10, the projection data of internal density distributions can be acquired at a high speed. On this account, particularly, the present invention can be effectively utilized for visualizing the distributions of the solids and gases in an opaque fluid which is difficult to be observed by visible rays, the phase distributions in the cross section of the flow path of a multiphase flow wherein gases and liquids flows as a mixture, or the distributions in the cross section of the flow path of a powder transport pipe line.

According to the device of the above-described embodiment, since the one line of detection pixel 4 group constructed on the single substrate 3 is formed by arranging mutually homogeneous detection pixels on the straight line at a constant pitch, the detected plane constitutes a plane, thereby easily enabling a high-resolution photographing.

When manufacturing the above-described detection module and the polygon-type semiconductor detector for use in a high-speed X-ray CT using the same, a single planar semiconductor substrate 3 is provided at one end portion on the printed circuit board 2, then on the detector substrate 3, a plurality of X-ray detection pixels 4 have electrodes machined by means of photolithography, and thus a single detector module 1 is manufactured. Then, by arranging a plurality of the above-described detector modules in a polygonal shape around the measuring area 10, an X-ray semiconductor detector can be formed. In this case, since each of the detection pixels 4 is manufactured with a high degree of accuracy by semiconductor processing, it is possible to eliminate errors in assembling, unlike the case where semiconductor pixels are discretely arranged on a circumference.

1. A polygon-type semiconductor detector for use in a high-speed X-ray CT, said detector comprising:
a plurality of detector modules each of which is formed by arranging a plurality of X-ray detection pixels unidirectionally on a single planar semiconductor substrate,
wherein said polygon-type semiconductor detector for use in a high-speed X-ray CT is formed by polygonally arranging the plurality of said detector modules around a measuring area.

2. A polygon-type semiconductor detector for use in a high-speed X-ray CT according to claim 1, wherein a CdTe semiconductor is used as said semiconductor substrate.

3. A polygon-type semiconductor detector for use in a high-speed X-ray CT according to claim 1, wherein said single semiconductor substrate is provided on a printed circuit board, and wherein the plurality of X-ray detection pixels formed on the semiconductor substrate is arranged along the longitudinal direction of said semiconductor substrate.

4. A polygon-type semiconductor detector for use in a high-speed X-ray CT according to claim 3, wherein the plurality of X-ray detection pixels on said single semiconductor substrate is arranged in a line.

5. A polygon-type semiconductor detector for use in a high-speed X-ray CT according to any one of claims 1 to 4, wherein electrodes of the X-ray detection pixels provided on the single semiconductor substrate are formed by means of photolithography.

6. A method for manufacturing a polygon-type semiconductor detector for use in a high-speed X-ray CT, said method comprising the steps of:
manufacturing a plurality of detector modules having a plurality of X-ray detection pixels on a single planar semiconductor substrate of each of the detector modules whose electrodes are made by photolithography; and
forming said X-ray semiconductor detector by polygonally arranging the plurality of said detector modules around the measuring area.
